(19) United States
(12) Patent Application Publication
(10) Pub. No.: US 2021/0240950 A1
(43) Pub. Date: Aug. 5, 2021

(54) CAPACITIVE CODE COMPARING

(71) Applicant: HEWLETT-PACKARD DEVELOPMENT COMPANY, L.P., Spring, TX (US)

(72) Inventors: Ning Ge, Palo Alto, CA (US); Helen A. Holder, Palto Alto, CA (US); Robert Ionescu, Palo Alto, CA (US)

(73) Assignee: HEWLETT-PACKARD DEVELOPMENT COMPANY, L.P., Spring, TX (US)

(21) Appl. No.: 17/052,068

(22) PCT Filed: Jun. 25, 2018
(86) PCT No.: PCT/US2018/039336

§ 371 Date: Oct. 30, 2020

(51) Int. Cl. G06K 7/10; G06F 13/10

(52) U.S. Cl. CPC G06K 7/10326; H03K 5/24; G06F 13/102

(57) ABSTRACT

Apparatus, systems, articles of manufacture, and methods to facilitate capacitive code comparing are disclosed. An example apparatus includes a comparator to receive a first portion of a first input and a second portion of a second input, the comparator including a capacitor. The example apparatus further includes a peripheral determination circuit to cause the capacitor to couple the first portion to the second portion; in response to coupling the first portion to the second portion, ground the capacitor; sense a current discharged by the grounded capacitor; and determine a Hamming distance of the first input and the second input based on the sensed current discharged by the capacitor.

### BACKGROUND

A Hamming distance, and/or other code comparison value, is used in a variety of fields including binary code corrections, noisy channel correction, information theory, coding theory, cryptography, telecommunications, etc. A Hamming distance is a number of positions at which two strings of equal position correspond to differing symbols. The Hamming distance corresponds to a minimum number of substitutions required to change one string into the other (e.g., the minimum number of errors that could have transformed one string to another). For example, the Hamming distance between “tomato” and “potato” is two because the first position (e.g., ‘t’ in “tomato” and ‘p’ in “potato”) and third position (e.g., ‘m’ “tomato” and ‘t’ in “potato”) of the two strings are different, while the rest of the positions of the two strings are the same.

### BRIEF DESCRIPTION OF THE DRAWINGS

FIG. 1 is an example capacitive code comparator.

FIG. 2 is an example circuit implementation of an example current sensor of the example capacitive code comparator of FIG. 1.

FIG. 3 is a block diagram of an example Hamming distance determiner of the example capacitive code comparator of FIG. 1

FIG. 4 is a flowchart representative of machine readable instructions which may be executed to implement the example Hamming distance determiner of FIG. 3.

FIG. 5 is a flowchart representative of machine readable instructions which may be executed to implement the example Hamming distance determiner of FIG. 3.

FIG. 6 is a block diagram of an example processing platform structured to execute the instructions of FIGS. 4 and 5 to implement the example Hamming distance determiner of FIG. 3.

The figures are not to scale. In general, the same reference numbers will be used throughout the drawing(s) and accompanying written description to refer to the same or like parts.

### DETAILED DESCRIPTION

Computer processing units (CPUs) or other digital circuits have been used to determine Hamming distance and/or other code comparisons/verifications by creating a sequence of Boolean values (e.g., digital values) indicating mismatches and matches between corresponding positions (e.g., values or parts) in two inputs. Conventional techniques for implementing a code comparator include complicated and/or expensive circuitry. Accordingly, conventional techniques correspond to low efficiency and high power consumed by a CPU digital circuit. Examples disclosed herein include a code comparator circuit with a smaller foot print, faster speed, and lower power consumption than conventional techniques by taking advantage of equal-potential isolation properties of a capacitor.

A capacitor is a passive two-terminal electrical component that stores potential energy in an electric field. In many examples, one terminal (e.g., end) of a capacitor is coupled to ground and the other terminal is coupled to a voltage supply. When there is a voltage differential across the terminals of the capacitor, the capacitor stores a charge corresponding to the voltage differential (e.g., stored charge (Q) is equal to the voltage differential (V=V1−V2) times the capacitance (C) of the capacitor, Q=V*C). In this manner, a capacitor may be used in electronics to store charge from a battery and discharge when the stored charge is needed to power part of a circuit. Equal-potential isolation is a property of a capacitor where, when the voltage at the two terminals of a capacitor are the same, the capacitor does not store charge (e.g., zero voltage differential corresponds to zero charge). Typically, equal-potential isolation is utilized by grounding both terminals of a capacitor (e.g., applying zero Volts to both terminals of the capacitor, Q=C*V=C*0=0). However, examples disclosed herein utilize equal-potential isolation of two voltages, that may or may not be ground, as a comparison for determining a Hamming distance.

Examples disclosed herein control switches to couple a first input to a second input via a capacitor and determine a Hamming distance, and/or other comparison data, based on whether or not the capacitor stored charged when the first input and the second input were coupled. For example, if a first input is a binary string corresponding to ‘110’ and a second input is a binary string corresponding to ‘100,’ examples disclosed herein utilize three capacitors to couple each part/position of the first input to the corresponding part/position of the second input to determine the Hamming distance. In such an example, a first capacitor may be used to couple the first position, ‘1’, of the first input to the first position, ‘1’, of the second input; a second capacitor may be used to couple the second position, ‘1’, of the first input to the second position, ‘0’, of the second input; and a third capacitor may be used to couple the third position, ‘0’, of the first input to the third position, ‘0’, of the second input, where each ‘1’ corresponds to a high voltage (e.g., 5 V) and each ‘0’ corresponds to a low voltage (e.g., 0 V). Accordingly, the first and third capacitors do not store charge because the voltage applied to both terminals of the first and third capacitors are the same when the first input is coupled to the second input via the capacitors. However, because the voltage applied to the terminals of the second capacitor are different, the second capacitor stores some charge (e.g., an amount of charge corresponding to the amount of voltage differential between the terminals). Examples disclosed herein include control switches to discharge all three capacitors and determine a Hamming distance between the two inputs based on the number of capacitors that discharge after the first and second inputs were coupled via the capacitors.

Using examples disclosed herein, a Hamming distance can be determined using minimal components and minimal power. Additionally, examples disclosed herein compare inputs faster than conventional code comparator techniques. Additionally, because any voltage can be applied to a capacitor, examples disclosed herein may be utilized for code comparisons with analog inputs without the need for an analog-to-digital converter, thereby further reducing the cost, speed, complexity, and size needed for code comparison.

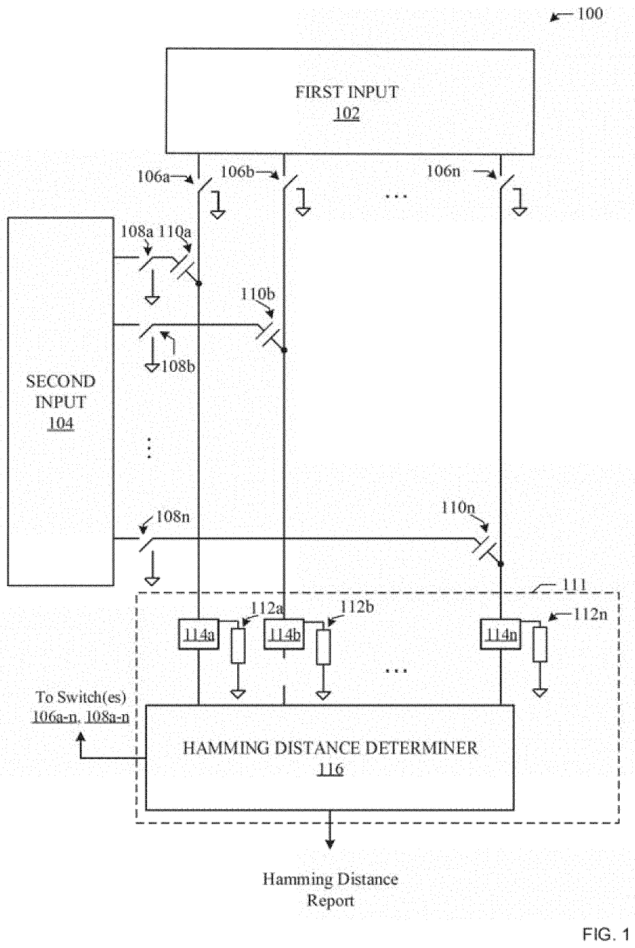

FIG. 1 illustrates an example capacitive code comparator 100 to compare an example first input 102 and an example second input 104. The example capacitive code comparator 100 includes the example first input 102, the example second input 104, example switches 106a-n, 108a-n, example capacitors 110a-n, and an example peripheral determination circuit 111. The example peripheral determination circuit 111 includes example loads 112a-n, example current senses 114a-n, and an example Hamming distance determiner 116.

The example first input 102 and the example second input 104 of FIG. 1 include a voltage, and in some examples multiple voltages, corresponding to values that may be compared with each other using the example Hamming distance determiner 116. For example, the first input 102 and the second input 104 may be strings of characters, binary values, and/or any other input corresponding to some voltage. In some examples, one of the inputs (e.g., the first input 102) may correspond to reference values, while the other input (e.g., the second input 104) may correspond to voltages to be compared to the reference values. For example, when the example capacitive code comparator 100 is utilized to compare measurements from an Internet of things (IoT) device or multiple IoT devices to reference values, the example first input 102 may correspond to measurements from IoT devices and the second input 104 may correspond to the analog reference values. In some examples, the analog values may be correspond to different values from different IoT sensors. The first input 102 and the second input 104 may include any number of values. The example first input 102 and the example second input 104 may be analog and/or digital values.

The example switches 106a-n, 108a-n of FIG. 1 control the connections of the example capacitors 110a. For example, the example switches 106a-n may couple a first side of the example capacitors 110a-n to the example first input 102 or to ground (e.g., depending on a control signal or multiple control signals sent to the example switches 106a-n). Additionally, the example switches 108a-n may couple a second side of the example capacitors 110a-n to the example second input 104 or to ground (e.g., a node that is grounded). Additionally, any one of the example switches 106a-n, 108a-n may open to create an open circuit between the respective inputs 102, 104 (e.g., where the example capacitors 110a are not grounded on one side or both sides and are not coupled to one or both of the example inputs 102, 104). The example switches 106a-n, 108a-n may include multiple switches to be open or closed to either the respective input or ground. In some examples, the example switches 106a-n, 108a-n may be implemented by a metal oxide field effect transistors (MOSFET) or multiple MOSFETS. In some examples, the switches 106a-n, 108a-n may be made with two-dimensional material (e.g., graphene, hexagon boron nitride, molybdenum disulfide, transition metal dichalcogenide monolayers, etc.). Such two-dimensional devices correspond to a small footprint.

The example capacitors 110a-n of FIG. 1 store charge and/or discharge based on a voltage differential between the two sides of the capacitors 110a-n. For example, if there is a voltage difference between the first side and the second side of the example capacitor 110a, the example capacitor 110a stores charge corresponding to the voltage differential. Accordingly, if (A) the switches 106a, 108a are to couple the first portion (e.g., part, position, element, piece, etc.) of the first input 102 to the first portion of the second input 104 and (B) the first portion of the first input 102 and the second portion of the second input 104 are the same voltage, the example capacitor 110a does not charge (e.g., there is no charging if there is not voltage differential across the capacitor 110a). Additionally, if (A) the switches 106a, 108a are to couple the first portion of the first input 102 to the first portion of the second input 104 and (B) the first portion of the first input 102 and the second portion of the second input 104 are the different voltages, the example capacitor 110a charges to an amount corresponding to the difference (e.g., the greater the difference, the more the charge). When the charged capacitor 110a is grounded (e.g., when the example switch 108a is closed to ground and the example switch 106a is open), the charged capacitor 110a discharges, causing current to flow toward or away from the example load 112a (e.g., depending on direction of the voltage differential during the charging). The amount of current being discharged corresponds to the amount of charge (e.g., based on the voltage differential between each input). In some examples, the capacitors 110a-n may be made with two-dimensional material (e.g., graphene, hexagon boron nitride, molybdenum disulfide, transition metal dichalcogenide monolayers, etc.). Such two-dimensional devices correspond to a small footprint.

The example current senses 114a-n of FIG. 1 are trans-impedance amplifiers (e.g., a current-to-voltage converter) to sense current being discharged by the example capacitors 110a-n. For example, the first example current sense 114a senses current being discharged by the example capacitor 110a. If the example current sense 114a senses a current, the example current sense 114a outputs a voltage corresponding to the discharged current to the example Hamming distance determiner 116. If the example current sense 114a does not sense a current, the example current sensor outputs 0 V to the example Hamming distance determiner 116. In this manner, the example Hamming distance determiner 116 can determine whether the first portion of the first input 102 and the first portion of the second input 104 are the same or different based on the voltage output of the current sense 114a.

The example Hamming distance determiner 116 of FIG. 1 compares the first input 102 to the second input 104 to determine a Hamming distance between the first input 102 and the second input 104. To determine the Hamming distance, the example Hamming distance determiner 116 sends control signals to the example switches 106a-n, 108a-n to close the example switches 106a-n, 108a-n to ground (e.g., to a node coupled to ground) to ensure that the example capacitors 110a-n are fully discharge (e.g., to reset the capacitors 110a-n) before coupling the first input 102 to the second input 104 via the capacitors 110a-n. Once the example capacitors 110a-n have been reset, the example Hamming distance determiner 116 transmits a control signal or multiple control signals to the example switches 106a-n, 108a-n to close the example switches 106a-n to the example first input 102 and to close the example switches 108a-n to the example second input 104, thereby causing respective parts of the first input 102 to couple to respective parts of the second input 104 via the example capacitors 110a-n. For example, a first portion of the first input 102 is coupled to a first portion of the second input 104 via the first capacitor 110a, a second portion of the first input 102 is coupled to a second portion of the second input 104 via the second capacitor 110b, etc. As disclosed above, if, when coupled, the first portion of the first input 102 is the same as the first portion of the second input 104, there is no voltage differential across the example capacitor 110a and the example capacitor 110a does not charge. If, when coupled, the first portion of the first input 102 is different than the first portion of the second input 104, there is a voltage differential across the example capacitor 110a and the capacitor 110a charges based on the differential. Likewise, the other example capacitors 110b-n charge or do not charge based on comparison to the respective parts of the first input 102 and the second input 104.

Once the example capacitors 110a-n have had sufficient time to charge, the example Hamming distance determiner 116 applies a control signal or multiple control signals to the example switches 106a-n to open and applies a control signal or multiple control signals to the example switches 108a-n to close to ground. In this manner, if any of the example capacitors 110a-n stored charge, the now grounded capacitors 110a-n discharge, causing current to flow to/from the respective example loads 112a-n. As disclosed above, the example current senses 114a-n sense any current and transmit a voltage representative of a discharging capacitor to the example Hamming distance determiner 116. The example Hamming distance determiner 116 determines a Hamming distance based on the output of the example current senses 114a-n. For example, if the example current senses 114a-b each sense a current and outputs a corresponding voltage to the example Hamming distance determiner 116 and the remaining current sensors do not measure current and do not output a voltage to the Hamming distance determiner 116, the example Hamming distance determiner 116 determines the Hamming distance to be ‘2’ (e.g., corresponding to the current discharged from the first and second capacitors 110a-b). In some examples, the Hamming distance determiner 116 may determine additional information from the output of the example current senses 114a-n. For example, the Hamming distance determiner 116 may be able to determine which parts of the first input 102 are larger or smaller than respective parts of the second input 104 based on the direction of the sensed current (e.g., corresponding to a negative voltage output by a current sensor) and/or the amount of different between parts of the first input 102 and respective parts of the second input 104 (e.g., based on the amount of voltage output by a current sensor). The example Hamming distance determiner 116 generates and outputs a Hamming distance report based on the determined Hamming distance and/or other determined data.

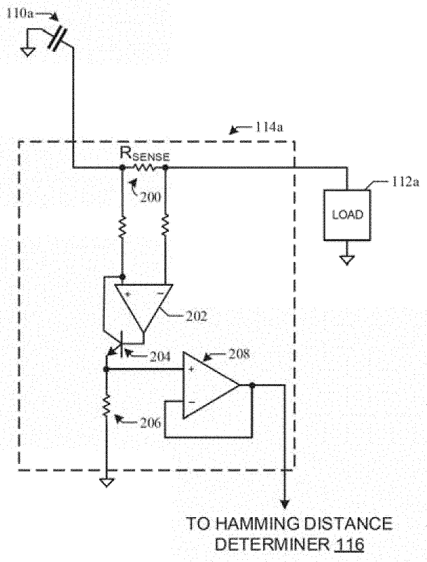

FIG. 2 illustrates an example circuit implementation of the example current sense 114a of FIG. 1 (e.g., a transimpedance amplifier). The example current sense 114a includes an example sensing resistor (Rsense) 200, an example operational amplifier 202, an example bipolar junction transistor (BJT) 204, an example resistor 206, and an example voltage follower 208. Although FIG. 2 is described in conjunction with the example current sense 114a of FIG. 1, FIG. 2 may be described in conjunction with any of the example current senses 114a-n.

The example Rsense 200 of FIG. 1 is a resistor that, when current flows through the Rsense 200, creates a voltage drop. In this manner, the example operational amplifier 202 can amplify the voltages across the Rsense 200 to determine when current is flowing across the example Rsense 200. For example, when a current is flowing from the example capacitor 110a (e.g., corresponding to the discharging of the example capacitor 110a), the voltage at the positive terminal of the example operational amplifier 202 is higher than the voltage at the negative terminal of the example operational amplifier 202, thereby causing the example operational amplifier 202 to output a amplified voltage corresponding to the difference to enable the example BJT 204 to turn on. Turning the example BJT 204 on allows current from the capacitor 110a to flow toward ground via the example resistor 206 corresponding to a voltage drop across the example resistor 206 that is input into the example voltage follower 208. The example voltage follower 208 outputs a voltage corresponding to the voltage seen at the positive terminal of the voltage follower 208 while drawing a very small amount of, or no, current. If no current is flowing through the example Rsense 200, the example operational amplifier 202 outputs zero volts to the example BJT 204, thereby turning off the example BJT 204. Accordingly, there will be no current flow through the example resistor 206 and the voltage output by the example voltage follower 208 is zero volts. The output of the example voltage follower 208 is coupled to the example Hamming distance determiner 116 of FIG. 1.

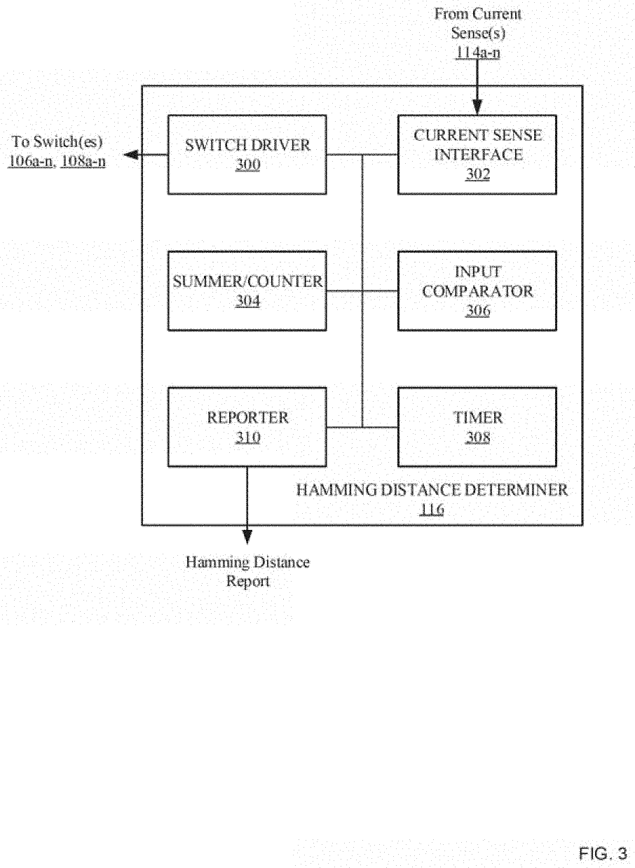

FIG. 3 is a block diagram of the example Hamming distance determiner 116 of FIG. 1. The example Hamming distance determiner 116 includes an example switch driver 300, an example current sense interface 302, an example summer/counter 304, an example input comparator 306, and an example reporter 310.

The example switch driver 300 of FIG. 3 sends a control signal or multiple control signals to one of the example switches 106a-n, 108a-n or multiple ones of the example switches 106a-n, 108a-n of FIG. 1. For example, the switch driver 300 may transmit a control signal or multiple control signals to the example switch 106a to open the switch 106a, close the switch to the first input 102, and/or close the switch 106a to ground. As disclosed above, the example switch 106a may include two switches. In such examples, the switch driver 300 may transmit a first signal to the first switch and a second signal to the second switch. The example switch driver 300 transmits the control signal or multiple control signals to the example switches 106a-n, 108a-n to (A) reset (e.g., discharge) the example capacitors 110a-n (e.g., by sending control signal(s) to the example switches 106a-n and/or the example switches 108a-n to couple the capacitors 110a-n to ground), (B) couple the first inputs 102 to the second input 104 via the example capacitors 110a-n (e.g., to have the capacitors 110a-n store charge based on a different between the inputs 102, 104), and/or (C) to discharge the example capacitors 110a-n after the capacitors 110a-n couple the two inputs 102, 104.

The example current sense interface 302 of FIG. 3 receives voltages from the example current senses 114a-n of FIG. 1. As disclosed above in conjunction with FIG. 2, if the example current senses 114a-n sense current flow corresponding to a discharge of a respective capacitor 110a-n, the corresponding current sensor transmits some voltage to the example sensor interface 302. The voltage represents a part (e.g., portion, position, element, piece, etc.) of the first input 102 and a corresponding part of the second input 104 being different. If one of the current senses 114a-n do not sense a current, the corresponding current senses 114a-n do not transmit a voltage (e.g., the output is zero volts) to the example sensor interface 302. The zero volts represents a part of the first input 102 and a corresponding part of the second input 104 being the same. In some example, the current sense interface 302 may be, or include, an analog-to-digital converter. In such examples, the analog-to-digital converter converts the received voltages from the current sense(s) into digital value corresponding to the sum of the voltages. In this manner, the example summer/counter 304 may determine the Hamming distance based on the digital sum determined by the analog-to-digital converter of the current sense interface 302.

The example summer/counter 304 of FIG. 3 counts the total number of received voltages from the example current senses 114a-n representative of some amount of discharge from the example capacitors 110a-n to determine the Hamming distance between the inputs 102, 104. For example, if three of the current senses 114a-n output a voltage representative of current flow corresponding to a discharging capacitor, the example summer/counter 304 determines the Hamming distance to be 3 (e.g., based on the three received voltages at the example current sense interface 302). In some examples, the summer/counter 304 may discard received voltages that are below a threshold value. For example, if the first input 102 and the second input 104 are analog inputs, the variation between the two may be very or relatively small corresponding to a very or relatively small voltage being output by the current sensor. Accordingly, the summer/counter 304 may discard such voltages from the count/sum when the voltage is below a threshold voltage. The threshold voltage may be based on user and/or manufacturer preferences and/or tolerances and/or may be adjustable.

When the example inputs 102, 104 are digital inputs, the summer/counter 304 of FIG. 3 may sum the total amount of current received by the current sense interface 302 from the current senses 114a-n. Because the digital inputs may correspond to one of two input value (e.g., high or low), if there is a difference between any two parts of the first input 102 and the second input 104, the amount of charge stored in the corresponding capacitors 110a-n will be the same. Accordingly, the sum of the currents (e.g., the voltages output by the current senses 114a-n represented of the currents) will correspond to the Hamming distance. For example, if the first input 102 is ‘110’ and the second input is ‘011’, the first comparator 100a and the third comparator 100c will storage the same amount of charge, when the respective parts of the inputs 102, 104 are coupled via the capacitors 100a-n. Accordingly, when the capacitors 110a-n are discharged, the first current sense 114a and the second current sense 114c will convert the discharging current to the same voltage (e.g., 5 V) and the other current senses (e.g., 114b) will output 0 V. In this manner, the summer/counter 304 can sum the received voltages (e.g., 5 V+5 V=10 V), resulting in a sum representative of the Hamming distance. As described above, the example current sense interface 302 may be, or include, an analog-to-digital converter to determine a digital value representative of the sum of the currents. In this manner, the summer/counter 304 can determine the Hamming distance by dividing a digital value representative of the sum (e.g., 10 V) by a digital value representative of the voltage corresponding to a difference between parts (e.g., 5 V). In some examples, because the output of the current sense(s) 114a-n may be negative, the example summer/counter 304 may sum the absolute value of each output of the current sensor(s) 114a-n. In the above example, the summer/counter 304 can determine that the Hamming distance between the first input 102 and the second input 104 is 2 (e.g., 10 V/5 V=2).

The example input comparator 306 of FIG. 3 processes the received voltages to provide additional information with the Hamming distance. For example, the input comparator 306 may process a received voltage corresponding to a first portion of the first input 102 and a first portion of the second input 104 to determine which portion is greater (e.g., based on whether the received voltage is positive or negative). For example, when the first portion of the first input 102 is greater than the first portion of the second input 104, the capacitor 110a charges in a first direction. When the capacitor 110a is discharged, the current flows in direction corresponding to the charge. Accordingly, the direction of the current corresponds to which input was larger. If the current is negative, the output of the current sense 114a is a negative voltage and if the current is positive, the output of the current sense 114a is a positive voltage. Accordingly, the example input comparator 306 can determine which parts of the first input 102 are larger than the respective parts of the second input 104 and which parts are smaller. Additionally, the example input comparators 306 can determine, when the first portion of the first input 102 is different than the first portion of the second input 104, how far apart the inputs are (e.g., a distance or magnitude between the corresponding parts of the first input 102 and second input 104) based on the amount of voltage received by the corresponding current sensor. For example, if the first portion of the first input 102 is much larger than the first portion of the second input 104, the example capacitor 110a charges a lot more than if the difference is very small. In this manner, when the example capacitor 110a is discharged, a larger difference between the inputs 102, 104 results in more current being discharged than a smaller difference between the inputs 102, 104. Accordingly, the example current sense 114a outputs a larger voltage when the difference between the inputs 102, 104 is larger and a smaller voltage with the difference between the inputs 102, 104 is smaller. The example input comparator 306 can process the received voltage information to determine how different each portion of the inputs 102, 104 is based on the received voltage(s). The example input comparator 306 may include such information with and/or in the reported Hamming distance.

The example timer 308 of FIG. 3 tracks an amount of time to ensure that that capacitors 110a-n have enough settling time (e.g., to charge and/or discharge), based on the characteristics of the capacitors 110a-n. Because the capacitors 110a-n do not instantaneously charge or discharge based on a voltage difference between the terminals, the voltage differential needs to be held for a duration of time to ensure that the capacitors 110a-n are fully charged or discharged to avoid false readings. Accordingly, the timer 308 tracks an amount of time to ensure that the capacitors 110a-n have sufficient time to settle during operation, thereby providing accurate comparison results.

The example reporter 310 of FIG. 3 generates a report based on the information determined by the example summer/counter 304 and/or the example input comparator 306. For example, the example reporter 310 may generate a report including the Hamming distance of the two inputs 102, 104 based on the output of the summer/counter 304. In some examples, the report may include information such as which parts of the inputs 102, 104 are larger/smaller than the other parts and by how much based on the information determined by the input comparator 306. The Hamming distance report may be displayed to a user via a user interface and/or another means. In some examples, the Hamming distance report may be a signal used by another processor to make adjustment to other devices. For example, if one or both of the inputs 102, 104 correspond to measured data from a network of IoT devices, the Hamming distance report may be transmitted to a processor to make adjustments to the network of IoT devices.

While an example manner of implementing the example Hamming distance determiner 116 of FIG. 1 is illustrated in FIG. 3, one, some, or all of the elements, processes and/or devices illustrated in FIG. 3 may be combined, divided, re-arranged, omitted, eliminated and/or implemented in any other way. Further, the example switch driver 300, the example current sense interface 302, the example summer/counter 304, the example input comparator 306, the example reporter 310, and/or, more generally, the example Hamming distance determiner 116 of FIG. 3 may be implemented by hardware, software, firmware and/or any combination of hardware, software and/or firmware. Thus, for example, any of the example switch driver 300, the example current sense interface 302, the example summer/counter 304, the example input comparator 306, the example reporter 310, and/or, more generally, the example Hamming distance determiner 116 of FIG. 3 could be implemented by an analog or digital circuit(s) or multiple analog or digital circuit(s), logic circuits, programmable processor(s), programmable controller(s), graphics processing unit(s) (GPU(s)), digital signal processor(s) (DSP(s)), application specific integrated circuit(s) (ASIC(s)), programmable logic device(s) (PLD(s)) and/or field programmable logic device(s) (FPLD(s)). When reading any of the apparatus or system claims of this patent to cover a purely software and/or firmware implementation, at least one of the example switch driver 300, the example current sense interface 302, the example summer/counter 304, the example input comparator 306, the example reporter 310, and/or, more generally, the example Hamming distance determiner 116 of FIG. 3 is/are hereby expressly defined to include a non-transitory computer readable storage device or storage disk such as a memory, a digital versatile disk (DVD), a compact disk (CD), a Blu-ray disk, etc. including the software and/or firmware. Further still, the example Hamming distance determiner 116 of FIG. 3 may include elements, processes and/or devices in addition to, or instead of, those illustrated in FIG. 3, and/or may include more than one of any or all of the illustrated elements, processes and devices. As used herein, the phrase “in communication,” including variations thereof, encompasses direct communication and/or indirect communication through an intermediary component or multiple intermediary components, and does not require direct physical (e.g., wired) communication and/or constant communication, but rather additionally includes selective communication at periodic intervals, scheduled intervals, aperiodic intervals, and/or one-time events.

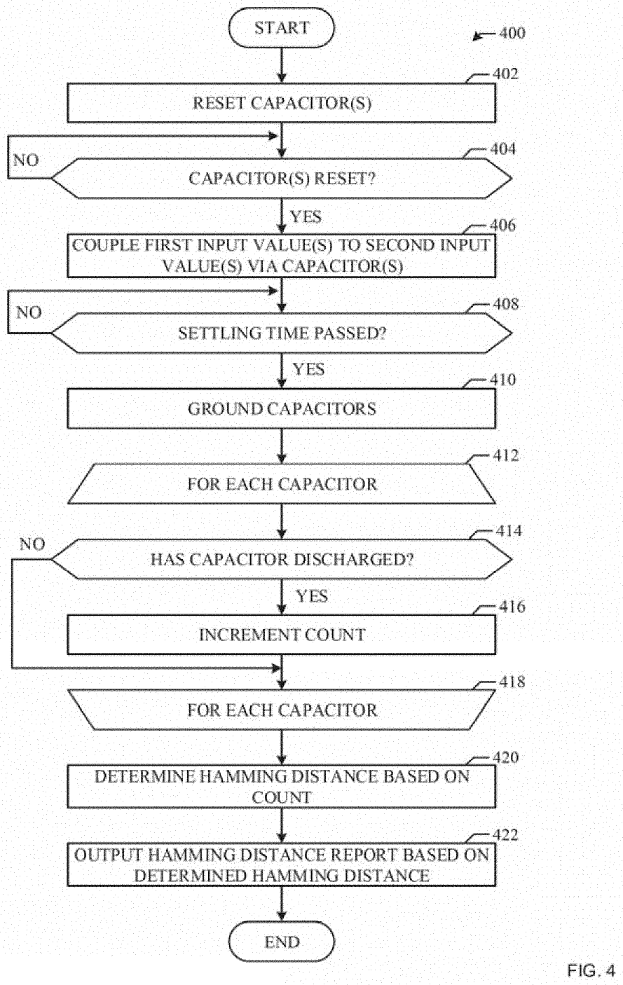

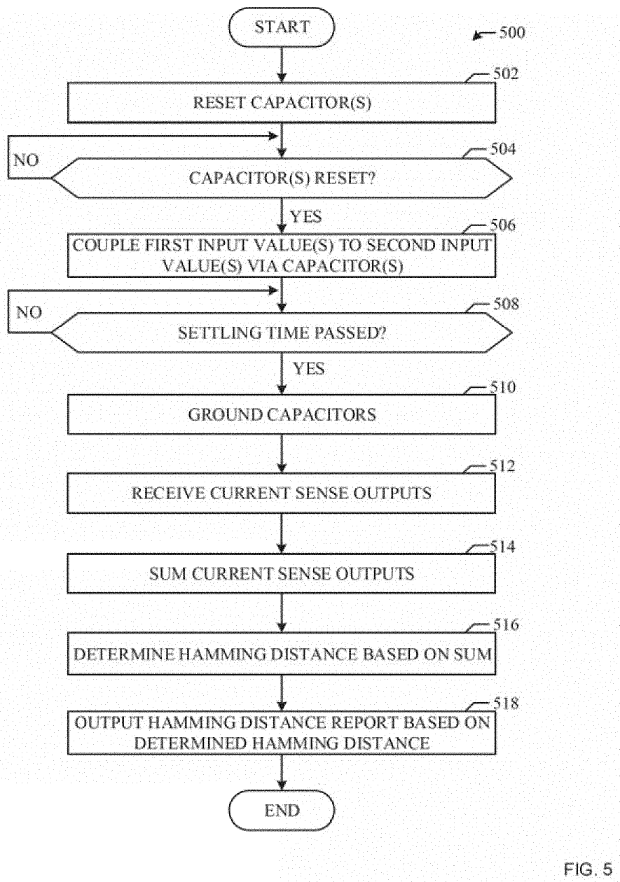

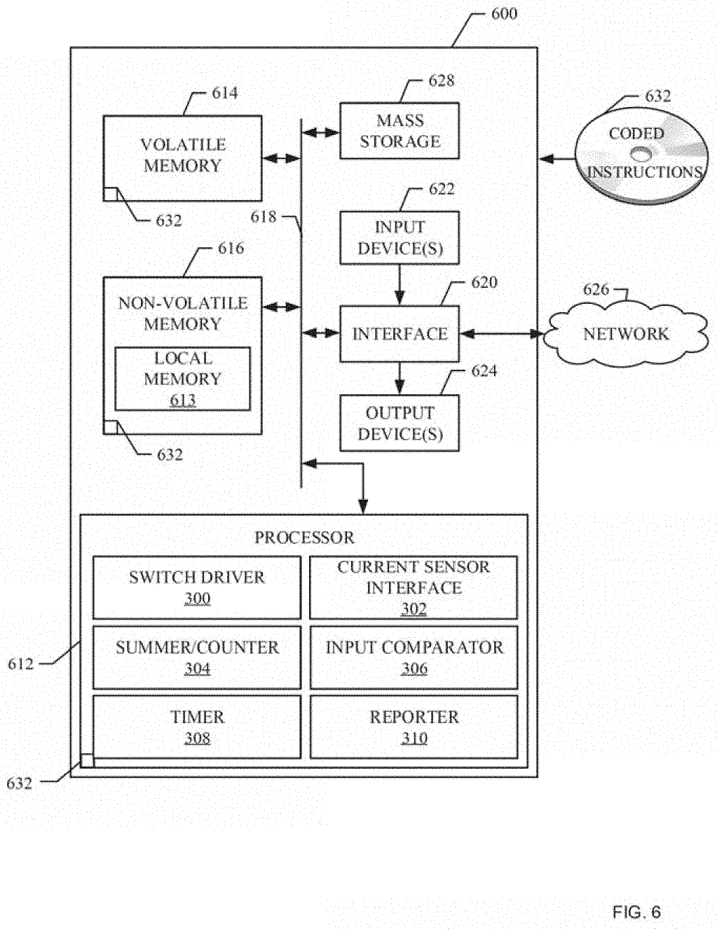

Flowcharts representative of example hardware logic, machine readable instructions, hardware implemented state machines, and/or any combination thereof for implementing the Hamming distance determiner 116 of FIG. 1 are shown in FIGS. 4 and 5. The machine readable instructions may be an executable program or portion of an executable program for execution by a computer processor such as the processor 612 shown in the example processor platform 600 discussed below in connection with FIG. 6. The program may be embodied in software stored on a non-transitory computer readable storage medium such as a CD-ROM, a floppy disk, a hard drive, a DVD, a Blu-ray disk, or a memory associated with the processor 612, but the entire program and/or parts thereof could alternatively be executed by a device other than the processor 612 and/or embodied in firmware or dedicated hardware. Further, although the example program is described with reference to the flowchart illustrated in FIGS. 4 and 5, many other methods of implementing the example Hamming distance determiner 116 may alternatively be used. For example, the order of execution of the blocks may be changed, and/or some of the blocks described may be changed, eliminated, or combined. Additionally or alternatively, any or all of the blocks may be implemented by a hardware circuit or multiple hardware circuits (e.g., discrete and/or integrated analog and/or digital circuitry, an FPGA, an ASIC, a comparator, an operational-amplifier (op-amp), a logic circuit, etc.) structured to perform the corresponding operation without executing software or firmware.

As disclosed above, the example processes of FIGS. 4 and 5 may be implemented using executable instructions (e.g., computer and/or machine readable instructions) stored on a non-transitory computer and/or machine readable medium such as a hard disk drive, a flash memory, a read-only memory, a compact disk, a digital versatile disk, a cache, a random-access memory and/or any other storage device or storage disk in which information is stored for any duration (e.g., for extended time periods, permanently, for brief instances, for temporarily buffering, and/or for caching of the information). As used herein, the term non-transitory computer readable medium is expressly defined to include any type of computer readable storage device and/or storage disk and to exclude propagating signals and to exclude transmission media.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc. may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, and (7) A with B and with C.

FIG. 4 is an example flowchart 400 representative of example machine readable instructions that may be executed by the example Hamming distance determiner 116 of FIG. 3 to determine the Hamming distance between two analog inputs 102, 104 using the example capacitive code comparator 100 of FIG. 1. Although the flowchart 400 of FIG. 4 is described in conjunction with the example capacitive code comparator 100 of FIG. 1, the flowchart 400 may be described in conjunction with any time of capacitive code comparator circuit.

At block 402, the example switch driver 300 resets the example capacitors 110a-n. The example switch driver 300 may reset the example capacitors 110a-n by sending control signal(s) to the example switches 106a-n and/or 108a-n to close to ground (e.g., grounding the capacitors 110a-n to remove previously stored charge). At block 404, the example timer 308 determines if sufficient time has passed to reset the capacitor(s) 110a-n. For example, the timer 308 may track the amount of time since the capacitor(s) 110a-n were reset and determines that the capacitors 110a-n have been reset based on the setting time of the capacitors 110a-n. If the example timer 308 determines that the capacitor(s) 110a-n have not had enough time to reset (block 404: NO), the process returns to block 404 until the capacitors 110a-n have had enough time to reset.

If the example timer 308 determines that the capacitor(s) 110a-n have had enough time to reset (block 404: YES), the example switch driver 300 couples the first input value(s) (e.g., of the first input 102) to the corresponding second input value(s) (e.g., of the second input 104) via the example capacitors 110a-n (block 406). The example switch driver 300 may couple the first input values to the second input values by sending control signal(s) to the example switches 106a-n and 108a-n to close the switches 106a-n to the first input 102 and close the switches 108a-n to the second input 104. Accordingly, the parts of the first input 102 are coupled to one end/terminal of the example capacitors 110a-n and the parts of the second input 104 are coupled to the other end/terminal of the example capacitors 110a-n. In this manner, if there is a difference between parts of the first input 102 and respective parts of the second input 104, the corresponding capacitors 110a-n store charge based on the difference.

At block 408, the example timer 308 determines the settling time has passed to sufficiently store charge in the capacitor(s) 110a-n. For example, the timer 308 may track the amount of time since the first input 102 and the second input 104 have been coupled via the capacitor(s) 110a-n based on the setting time of the capacitors 110a-n. If the example timer 308 determines that the settling time has not been passed (block 408: NO), the process returns to block 408 until the settling time passes. If the example timer 308 determines that the capacitor(s) 110a-n have had enough time to reset (block 408: YES), the example switch driver 300 grounds the example capacitors 110a-n (block 410). The example switch driver 300 may ground the example capacitors 110a-n by opening the example switches 106a-n and closing the example switches 108a-n to ground. As disclosed above, grounding the capacitors 110a-n allows the capacitors 110a-n to discharge if the capacitors 110a-n have stored charged (e.g., at block 406). For each capacitor of the capacitors 110a-n (block 412-block 414), the example current summer/counter 304 determines if the capacitor has discharged (block 418). The example summer/counter 304 determines if the capacitor (e.g., one of the example capacitors 110a-n or multiple of the example capacitors 110a-n) discharges if the corresponding current sensor outputs a voltage above a threshold amount of voltage. The voltage output by the corresponding current sensor is received by the example current sense interface 302.

If the example summer/counter 304 determines that the corresponding capacitor has not discharged (block 414: NO), the example summer/counter 304 does not increment a count (e.g., corresponding to the Hamming distance) and the process continues for the remaining capacitor. If the example summer/counter 304 determines that the corresponding capacitor has discharged (block 414: YES), the example summer/counter 304 increments the count (e.g., corresponding to Hamming distance) (block 416). Once the example Hamming distance determiner 116 determines if each capacitor of the capacitors 110a-n has been discharged, the example summer/counter 304 determines the Hamming distance based on the count (block 420). In some examples, the input comparator 306 may process the voltages received from the example current senses 114a-n (e.g., via the example current sense interface 302) to determine more detailed information corresponding to the Hamming distance (e.g., which inputs are greater/smaller, the amount of difference between inputs, etc.). At block 422, the example reporter 310 generates and outputs a Hamming distance report based on the determined Hamming distance. In some examples, the reporter 310 may include the additional information determined by the example input comparator 306 in the Hamming distance report. As disclosed above in conjunction with FIG. 3, the reporter 310 may output the report to a user via a user interface and/or may output the report as a signal to another processor.

FIG. 5 is an example flowchart 500 representative of example machine readable instructions that may be executed by the example Hamming distance determiner 116 of FIG. 3 to determine the Hamming distance between two digital inputs 102, 104 using the example capacitive code comparator 100 of FIG. 1. Although the flowchart 500 of FIG. 5 is described in conjunction with the example capacitive code comparator 100 of FIG. 1, the flowchart 500 may be described in conjunction with any time of capacitive code comparator circuit.

At block 502, the example switch driver 300 resets the example capacitors 110a-n. The example switch driver 300 may reset the example capacitors 110a-n by sending control signal(s) to the example switches 106a-n and/or 108a-n to close to ground (e.g., grounding the capacitors 110a-n to remove previously stored charge). At block 504, the example timer 308 determines if sufficient time has passed to reset the capacitor(s) 110a-n. For example, the timer 308 may track the amount of time since the capacitor(s) 110a-n were reset and determines that the capacitors 110a-n have been reset based on the setting time of the capacitors 110a-n. If the example timer 308 determines that the capacitor(s) 110a-n have not had enough time to reset (block 504: NO), the process returns to block 504 until the capacitors 110a-n have had enough time to reset.

If the example timer 308 determines that the capacitor(s) 110a-n have had enough time to reset (block 504: YES), the example switch driver 300 couples the first input value(s) (e.g., of the first input 102) to the corresponding second input value(s) (e.g., of the second input 104) via the example capacitors 110a-n (block 506). The example switch driver 300 may couple the first input values to the second input values by sending control signal(s) to the example switches 106a-n and 108a-n to close the switches 106a-n to the first input 102 and close the switches 108a-n to the second input 104. Accordingly, the parts of the first input 102 are coupled to one end/terminal of the example capacitors 110a-n and the parts of the second input 104 are coupled to the other end/terminal of the example capacitors 110a-n. In this manner, if there is a difference between parts of the first input 102 and respective parts of the second input 104, the corresponding capacitors 110a-n store charge based on the difference.

At block 508, the example timer 308 determines the settling time has passed to sufficiently store charge in the capacitor(s) 110a-n. For example, the timer 308 may track the amount of time since the first input 102 and the second input 104 have been coupled via the capacitor(s) 110a-n based on the setting time of the capacitors 110a-n. If the example timer 308 determines that the settling time has not been passed (block 508: NO), the process returns to block 508 until the settling time passes. If the example timer 308 determines that the capacitor(s) 110a-n have had enough time to reset (block 508: YES), the example switch driver 300 grounds the example capacitors 110a-n (block 510). The example switch driver 300 may ground the example capacitors 110a-n by opening the example switches 106a-n and closing the example switches 108a-n to ground. As disclosed above, grounding the capacitors 110a-n allows the capacitors 110a-n to discharge if the capacitors 110a-n have stored charged (e.g., at block 506).

At block 512, the example current sense interface 302 receives the outputs of the current sense(s) 114a-n (e.g., voltages representative of discharging current). At block 514, the example summer/counter 304 sums the received current sense outputs. In some examples, the summer/counter 304 takes the absolute value of the current sense outputs before summing. In some examples, the summer/counter 304 converts the received current sense outputs into a digital value corresponding to a sum of the currents. As described above, because the comparison corresponds to a digital comparison, if the respective parts of the inputs 102, 104 are the same a preset current will be discharged from each capacitor 110a-n storing charge. Accordingly, the sum of the received current sense outputs corresponds to the Hamming distance.

At block 516, the example summer/counter 304 determines the Hamming distance based on the sum of the outputs of the current senses 114a-n. For example, if the sum of the current senses 114a-n (e.g., a digital value representative of the sum of the current senses 114a-n) is 30V and the voltage corresponding to a difference between two respective parts of the inputs 102, 104 is 3 V, the summer/counter 304 determines the Hamming distance to be 10 based on the digital representations of the sum and the voltage differential of two different respective parts (e.g., 30 V/3 V=10). In some examples, the input comparator 306 may process the voltages received from the example current senses 114a-n (e.g., via the example current sense interface 302) to determine more detailed information corresponding to the Hamming distance (e.g., which inputs are greater/smaller, the amount of difference between inputs, etc.). At block 518, the example reporter 310 generates and outputs a Hamming distance report based on the determined Hamming distance. In some examples, the reporter 310 may include the additional information determined by the example input comparator 306 in the Hamming distance report. As disclosed above in conjunction with FIG. 3, the reporter 310 may output the report to a user via a user interface and/or may output the report as a signal to another processor.

FIG. 6 is a block diagram of an example processor platform 600 structured to execute the instructions of FIGS. 4 and 5 to implement the Hamming distance determiner 116 of FIG. 3. The processor platform 600 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset or other wearable device, or any other type of computing device.

The processor platform 600 of the illustrated example includes a processor 612. The processor 612 of the illustrated example is hardware. For example, the processor 612 can be implemented by one or more integrated circuits, logic circuits, microprocessors, GPUs, DSPs, or controllers from any desired family or manufacturer. The hardware processor may be a semiconductor based (e.g., silicon based) device. In this example, the processor implements the example switch driver 300, the example current sense interface 302, the example summer/counter 304, the example input comparator 306, the example timer 308 and/or the example reporter 310.

The processor 612 of the illustrated example includes a local memory 613 (e.g., a cache). The processor 612 of the illustrated example is in communication with a main memory including a volatile memory 614 and a non-volatile memory 616 via a bus 618. The volatile memory 614 may be implemented by Synchronous Dynamic Random Access Memory (SDRAM), Dynamic Random Access Memory (DRAM), RAMBUS® Dynamic Random Access Memory (RDRAM®) and/or any other type of random access memory device. The non-volatile memory 616 may be implemented by flash memory and/or any other desired type of memory device. Access to the main memory 614, 616 is controlled by a memory controller.

The processor platform 600 of the illustrated example also includes an interface circuit 620. The interface circuit 620 may be implemented by any type of interface standard, such as an Ethernet interface, a universal serial bus (USB), a Bluetooth® interface, a near field communication (NFC) interface, and/or a PCI express interface.

In the illustrated example, an input device 622 or multiple input devices 622 are connected to the interface circuit 620. The input device(s) 622 permit(s) a user to enter data and/or commands into the processor 612. The input device(s) can be implemented by, for example, an audio sensor, a microphone, a camera (still or video), a keyboard, a button, a mouse, a touchscreen, a track-pad, a trackball, isopoint and/or a voice recognition system.

An output devices 624 or multiple output devices 624 are also connected to the interface circuit 620 of the illustrated example. The output devices 624 can be implemented, for example, by display devices (e.g., a light emitting diode (LED), an organic light emitting diode (OLED), a liquid crystal display (LCD), a cathode ray tube display (CRT), an in-place switching (IPS) display, a touchscreen, etc.), a tactile output device, a printer and/or speaker. The interface circuit 620 of the illustrated example, thus, typically includes a graphics driver card, a graphics driver chip and/or a graphics driver processor.

The interface circuit 620 of the illustrated example also includes a communication device such as a transmitter, a receiver, a transceiver, a modem, a residential gateway, a wireless access point, and/or a network interface to facilitate exchange of data with external machines (e.g., computing devices of any kind) via a network 626. The communication can be via, for example, an Ethernet connection, a digital subscriber line (DSL) connection, a telephone line connection, a coaxial cable system, a satellite system, a line-of-site wireless system, a cellular telephone system, etc.

The processor platform 600 of the illustrated example also includes a mass storage devices 628 or multiple mass storage devices 628 for storing software and/or data. Examples of such mass storage devices 628 include floppy disk drives, hard drive disks, compact disk drives, Blu-ray disk drives, redundant array of independent disks (RAID) systems, and digital versatile disk (DVD) drives.

The machine executable instructions 632 of FIGS. 4 and 5 may be stored in the mass storage device 628, in the volatile memory 614, in the non-volatile memory 616, and/or on a removable non-transitory computer readable storage medium such as a CD or DVD.

From the foregoing, it will be appreciated that example methods, apparatus and articles of manufacture have been disclosed that facilitate capacitive code comparing. Using examples disclosed herein, a Hamming distance can be determined using minimal components and minimal power. Additionally, examples disclosed herein are faster than conventional code comparator techniques. Additionally, because any voltage can be applied to a capacitor, examples disclosed herein may be utilized for code comparisons for analog inputs without the need for an analog-to-digital converter, thereby further reducing the cost, speed, complexity, and size needed for code comparison.

An apparatus for capacitive code comparing is disclosed. In some examples, the apparatus includes a comparator to receive a first portion of a first input and a second portion of a second input, the comparator including a capacitor; a peripheral determination circuit to cause the capacitor to couple the first portion to the second portion; in response to coupling the first portion to the second portion, ground the capacitor; sense a current discharged by the grounded capacitor; and determine a Hamming distance of the first input and the second input based on the sensed current discharged by the capacitor.

In some examples, the apparatus further includes first and second switches, the peripheral determination circuit to couple the first portion to the second portion and to ground the capacitor by controlling the first and second switches.

In some examples, the peripheral determination circuit is to cause the capacitor to couple the first portion to the second portion by applying a control signal to couple the first portion to a first terminal of the capacitor and couple the second portion to a second terminal of the capacitor.

In some examples, the peripheral determination circuit includes a processor; and a trans-impedance amplifier to sense the current discharged by the grounded capacitor.

In some examples, the processor is to increment a count if the trans-impedance amplifier senses the current, the count corresponding to the Hamming distance.

In some examples, the capacitor is a first capacitor, wherein the comparator to receive a third portion of the first input and a fourth portion of the second input, the comparator including a second capacitor; and the processor to cause the second capacitor to couple the third portion to the fourth portion; and in response to coupling the third portion to the fourth portion, ground the second capacitor.

In some examples, the trans-impedance amplifier is a first trans-impedance amplifier and the current is a first current, further including a second trans-impedance amplifier to sense whether a second current has been discharged by the second grounded capacitor, the processor to determine the Hamming distance of the first input and the second input based on whether the second trans-impedance amplifier senses the second current.

In some examples, the processor is to sum the first current and the second current, the sum corresponding to the Hamming distance.

In some examples, the peripheral determination circuit is to determine whether the first portion is larger or smaller than the second portion based on an output of the trans-impedance amplifier.

In some examples, the peripheral determination circuit is to determine a distance between the first portion and the second portion based on an output of the trans-impedance amplifier.

In some examples, when the first portion is the same as the second portion, no current is discharged by the grounded capacitor and, when the first portion is different than the second portion, a current is discharged by the grounded capacitor.

An example tangible computer readable storage medium is disclosed comprising instructions which, when executed, cause a processor to at least: cause a capacitor to couple a first portion of a first input to a second portion of a second input; and in response to coupling the first portion to the second portion, transmit a control signal to ground the capacitor; and in response to transmitting the control signal, determine a Hamming distance of the first input and the second input based on an amount of current discharged by the capacitor.

In some examples, the amount of current being discharged by the capacitor is determined by an amplifier and converted into a voltage, the instructions to cause the processor to determine the Hamming distance based on the voltage.

In some examples, the instructions cause the processor to cause the capacitor to couple the first portion to the second portion by applying a second control signal to a switch, the second control signal causing the first portion to couple to a first terminal of the capacitor and the second portion to couple to a second terminal of the capacitor.

In some examples, the instructions cause the processor to ground the capacitor by transmitting the control signal to cause a switch to close to a grounded node.

In some examples, the instructions cause the processor to increment a count if the discharged current is above a threshold.

In some examples, the instructions cause the processor to: cause a second capacitor to couple a third portion of the first input to a fourth portion of the second input; in response to coupling the third portion to the fourth portion, transmit the control signal to ground the second capacitor; and, in response to transmitting the control signal, determine the Hamming distance of the first and the second input based on a second amount of current discharged by the second capacitor.

In some examples, the instructions cause the processor to determine whether the first portion is larger or smaller than the second portion based on the amount of current.

In some examples, the instructions cause the processor to determine a distance between the first portion and the second portion based on the amount of current.

In some examples, when the first portion is the same as the second portion, no current is discharged by the grounded capacitor and, when the first portion is different than the second portion, a current is discharged by the grounded capacitor.

An example method for capacitive code comparing is disclosed. The example method includes coupling a first portion of a first input to a first terminal of a capacitor and coupling a second portion of a second input to a second terminal of the capacitor; in response to coupling the first portion to the second portion via the capacitor, grounding the capacitor; and in response to grounding the capacitor, determining, by executing an instruction using a processor, a Hamming distance of the first input and the second input based on an amount of current discharged by the grounded capacitor.

In some examples, the determining of the Hamming distance is based on a voltage corresponding to the amount of current discharged by the capacitor.

Although certain example methods, apparatus and articles of manufacture have been disclosed herein, the scope of coverage of this patent is not limited thereto. On the contrary, this patent covers all methods, apparatus and articles of manufacture fairly falling within the scope of the claims of this patent.

What is claimed is:

1. An apparatus for capacitive code comparing, the apparatus comprising:
a comparator to receive a first portion of a first input and a second portion of a second input, the comparator including a capacitor;
a peripheral determination circuit to:
cause the capacitor to couple the first portion to the second portion;
in response to coupling the first portion to the second portion, ground the capacitor;
sense a current discharged by the grounded capacitor; and
determine a Hamming distance of the first input and the second input based on the sensed current discharged by the capacitor.

2. The apparatus of claim 1, further including first and second switches, the peripheral determination circuit to couple the first portion to the second portion and to ground the capacitor by controlling the first and second switches.

3. The apparatus of claim 1, wherein the peripheral determination circuit is to cause the capacitor to couple the first portion to the second portion by applying a control signal to couple the first portion to a first terminal of the capacitor and couple the second portion to a second terminal of the capacitor.

4. The apparatus of claim 1, wherein the peripheral determination circuit includes:
a processor; and
a trans-impedance amplifier to sense the current discharged by the grounded capacitor.

5. The apparatus of claim 4, wherein the processor is to increment a count if the trans-impedance amplifier senses the current, the count corresponding to the Hamming distance.

6. The apparatus of claim 4, wherein the capacitor is a first capacitor, wherein:
the comparator to receive a third portion of the first input and a fourth portion of the second input, the comparator including a second capacitor; and
the processor to:
cause the second capacitor to couple the third portion to the fourth portion; and
in response to coupling the third portion to the fourth portion, ground the second capacitor.

7. The apparatus of claim 6, wherein the trans-impedance amplifier is a first trans-impedance amplifier and the current is a first current, further including a second trans-impedance amplifier to sense whether a second current has been discharged by the second grounded capacitor, the processor to determine the Hamming distance of the first input and the second input based on whether the second trans-impedance amplifier senses the second current.

8. The apparatus of claim 7, wherein the processor is to sum the first current and the second current, the sum corresponding to the Hamming distance.

9. The apparatus of claim 4, wherein the peripheral determination circuit is to determine whether the first portion is larger or smaller than the second portion based on an output of the trans-impedance amplifier.

10. The apparatus of claim 4, wherein the peripheral determination circuit is to determine a distance between the first portion and the second portion based on an output of the trans-impedance amplifier.

11. The apparatus of claim 1, wherein, when the first portion is the same as the second portion, no current is discharged by the grounded capacitor and, when the first portion is different than the second portion, a current is discharged by the grounded capacitor.

12. A tangible computer readable storage medium comprising instructions which, when executed, cause a processor to at least:
cause a capacitor to couple a first portion of a first input to a second portion of a second input; and
in response to coupling the first portion to the second portion, transmit a control signal to ground the capacitor; and
in response to transmitting the control signal, determine a Hamming distance of the first input and the second input based on an amount of current discharged by the capacitor.

13. The computer readable storage medium of claim 12, wherein the amount of current being discharged by the capacitor is determined by an amplifier and converted into a voltage, the instructions to cause the processor to determine the Hamming distance based on the voltage.

14. The computer readable storage medium of claim 12, wherein the instructions cause the processor to cause the capacitor to couple the first portion to the second portion by applying a second control signal to a switch, the second control signal causing the first portion to couple to a first terminal of the capacitor and the second portion to couple to a second terminal of the capacitor.

15. The computer readable storage medium of claim 12, wherein the instructions cause the processor to ground the capacitor by transmitting the control signal to cause a switch to close to a grounded node.

16. The computer readable storage medium of claim 12, wherein the instructions cause the processor to increment a count if the discharged current is above a threshold.

17. The computer readable storage medium of claim 12, wherein the instructions cause the processor to:
cause a second capacitor to couple a third portion of the first input to a fourth portion of the second input;
in response to coupling the third portion to the fourth portion, transmit the control signal to ground the second capacitor; and
in response to transmitting the control signal, determine the Hamming distance of the first and the second input based on a second amount of current discharged by the second capacitor.

18. The computer readable storage medium of claim 12, wherein the instructions cause the processor to determine whether the first portion is larger or smaller than the second portion based on the amount of current.

19. The computer readable storage medium of claim 12, wherein the instructions cause the processor to determine a distance between the first portion and the second portion based on the amount of current.

20. A method for capacitive code comparing, the method comprising:
coupling a first portion of a first input to a first terminal of a capacitor and coupling a second portion of a second input to a second terminal of the capacitor;
in response to coupling the first portion to the second portion via the capacitor, grounding the capacitor; and
in response to grounding the capacitor, determining, by executing an instruction using a processor, a Hamming distance of the first input and the second input based on an amount of current discharged by the grounded capacitor.

21. The method of claim 20, wherein the determining of the Hamming distance is based on a voltage corresponding to the amount of current discharged by the capacitor.
